(19) United States
(12) Patent Application Publication
(10) Pub. No.: US 2007/0134869 A1
(43) Pub. Date: Jun. 14, 2007

(54) Method for fabricating semiconductor device

(75) Inventors: Ky-Hyun Han, Kyoungki-do (KR); Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor, Inc.

(21) Appl. No.: 11/479,244

(22) Filed: Jun. 29, 2006

(30) Foreign Application Priority Data
Dec. 13, 2005 (KR) 2005-0122472

(51) Int. Cl. H01L 21/8238

(52) U.S. Cl. 438/221; 257/E21.546

(57) ABSTRACT

A method for fabricating a semiconductor device includes etching a predetermined portion of a substrate to form a device isolation region, forming a barrier layer over the substrate and the device isolation region, selectively etching the barrier layer to expose a bottom surface of the device isolation region, etching the exposed bottom surface of the device isolation region using the barrier layer as an etch barrier, performing an isotropic etching process onto a bottom portion of the device isolation region, and forming a device isolation structure filled into the device isolation region.

### FIELD OF THE INVENTION

The present invention relates to a method for fabricating a semiconductor device, and more particularly, to a method for fabricating a device isolation region of a semiconductor device.

### DESCRIPTION OF RELATED ARTS

As semiconductor devices have become more highly integrated, miniaturized, and faster, the distance between devices in a wafer has become smaller. Even if the semiconductor devices have been highly integrated and miniaturized, the minimum amount of voltage for operating the semiconductor device should be maintained. As the size of semiconductor devices has been reduced down to a nano level micro device, a device isolation process for isolating devices during a device developing process has become extremely important. It is also important to maintain more than a certain distance between the isolated devices.

FIGS. 1A and 1B illustrate cross-sectional views of a semiconductor device obtained by a typical fabrication method.

Referring to FIG. 1A, a pad nitride layer 12 and a pad oxide layer 13 are formed over a substrate 11 and patterned thereafter. The substrate 11 is etched to form trenches 14 using the pad nitride layer 12 and the pad oxide layer 13 as an etch mask.

As shown in FIG. 1B, device isolation regions 15 are formed in the trenches 14. In more detail, an insulation layer is formed over the substrate structure until the trenches 14 are filled. Then, a planarizing process is performed to form the device isolation regions 15, and recess channels 16 are formed in the substrate 11.

FIG. 2 illustrates micrographic views of a typical semiconductor device. Horns 100 are generated between device isolation regions and recess channels. The horns 100 may become a source of leakage current.

Due to the large-scale integration of semiconductor devices, cell patterns have become denser and the distance between cells has decreased. Thus, it has become difficult to maintain the necessary distance between devices, for use in device isolation regions. Consequently, the device isolation regions may not function properly, often resulting in interferences between the devices. Thus, the current or electric charges flowing toward each of the cells flow into the edge of each device isolation region and eventually flow into devices on the other side, generally generating the leakage current.

### SUMMARY OF THE INVENTION

It is, therefore, an object of the present invention to provide a method for fabricating a semiconductor device with a device isolation region, which can reduce a leakage current generation by removing horns and increasing a distance between devices.

In accordance with an aspect of the present invention, there is provided a method for fabricating a semiconductor device, including: etching a predetermined portion of a substrate to form a device isolation region; forming a barrier layer over the substrate and the device isolation region; selectively etching the barrier layer to expose a bottom surface of the device isolation region; etching the exposed bottom surface of the device isolation region using the barrier layer as an etch barrier; performing an isotropic etching process onto a bottom portion of the device isolation region; and forming a device isolation structure filled into the device isolation region.

### BRIEF DESCRIPTION OF THE DRAWINGS

The above and other objects and features of the present invention will become better understood with respect to the following description of the exemplary embodiments given in conjunction with the accompanying drawings, in which:

FIGS. 1A and 1B are cross-sectional views illustrating a typical method for fabricating a semiconductor device;

FIG. 2 illustrates micrographic views of a typical semiconductor device; and

FIGS. 3A to 3F are cross-sectional views illustrating a method for fabricating a semiconductor device in accordance with a specific embodiment of the present invention.

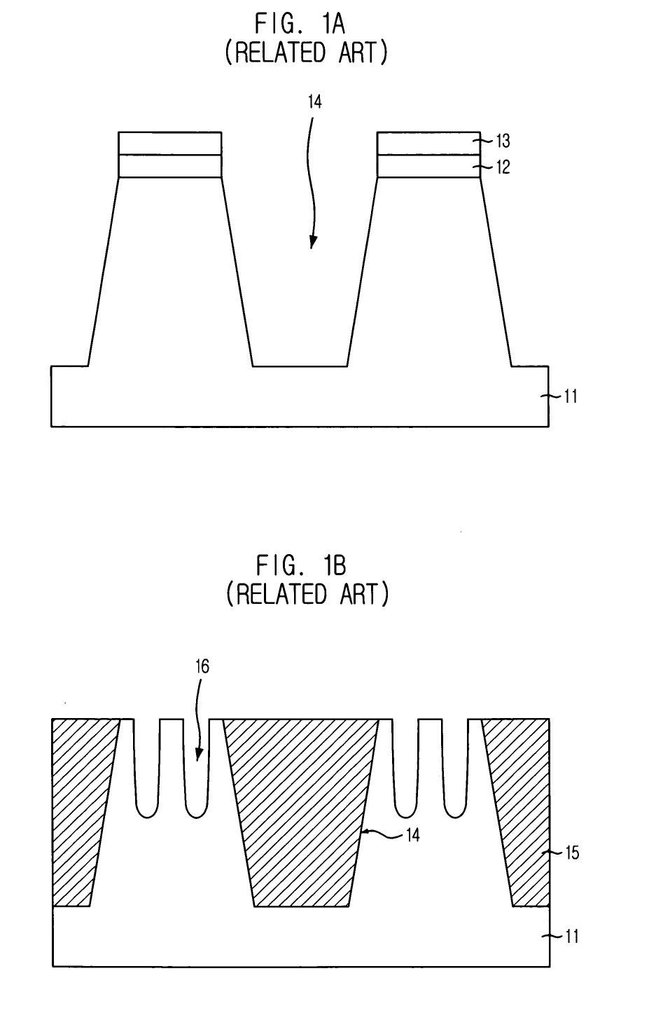

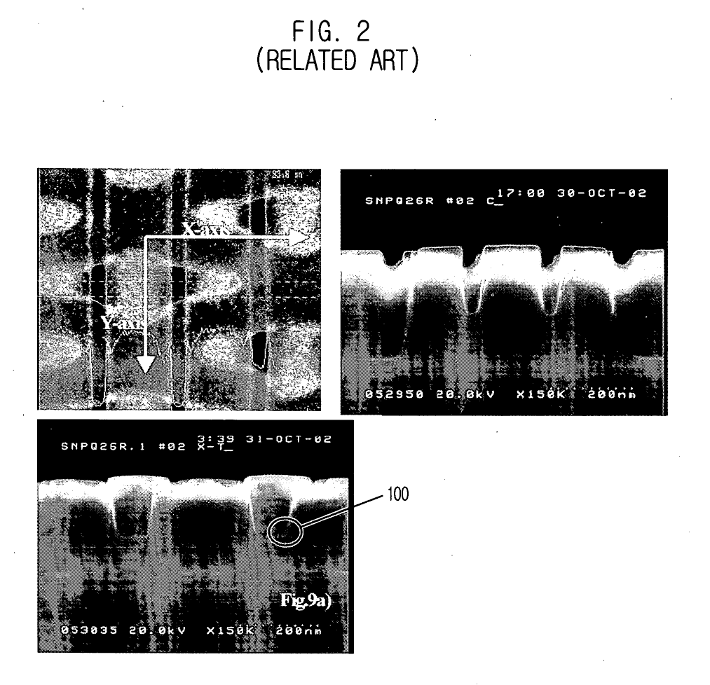

### DETAILED DESCRIPTION OF THE INVENTION

A method for fabricating a semiconductor device in accordance with exemplary embodiments of the present invention will be described in detail with reference to the accompanying drawings.

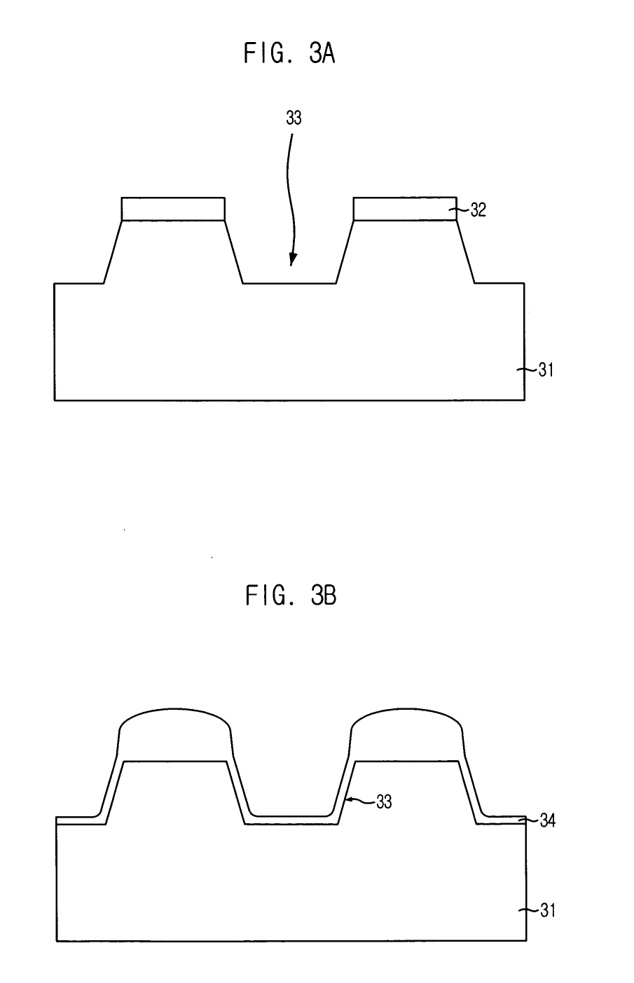

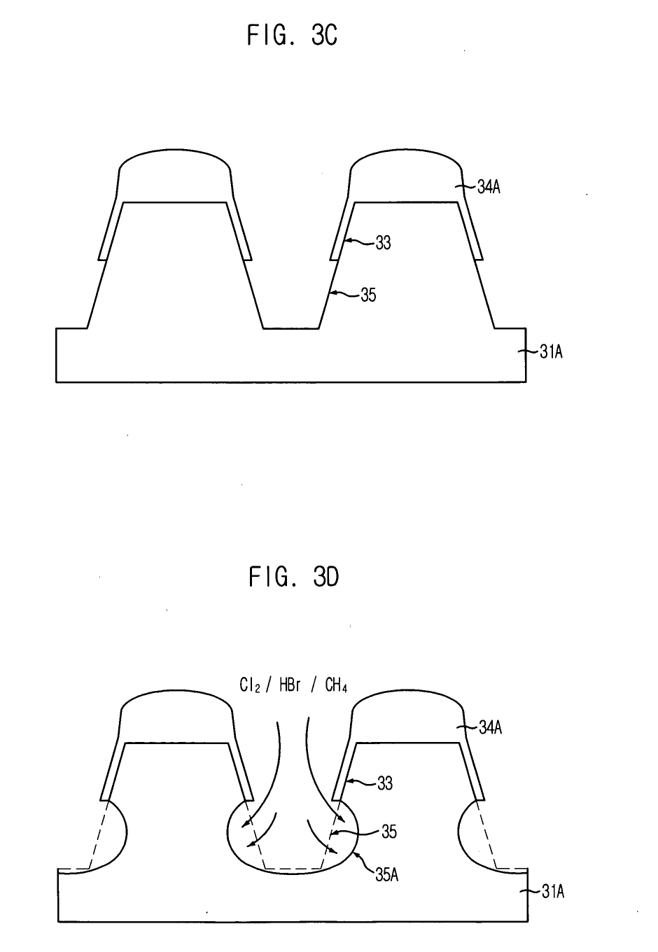

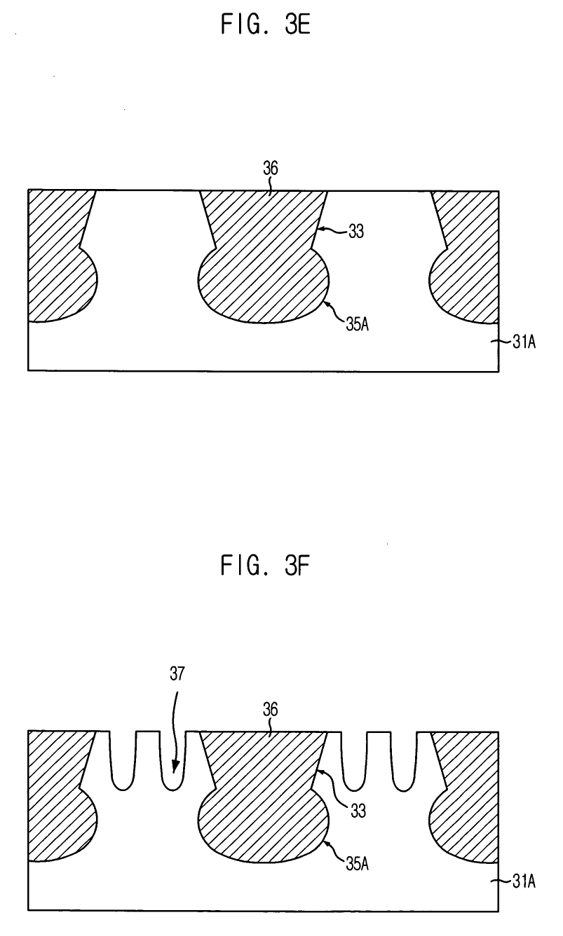

FIGS. 3A to 3F illustrate cross-sectional views to describe a method for fabricating a semiconductor device in accordance with a specific embodiment of the present invention.

FIG. 3A illustrates a substrate structure including a substrate 31, a photoresist pattern 32, and device isolation regions 33. In more detail, a photoresist layer is formed over the substrate 31. Then, photo-exposure and developing processes are performed to form the photoresist pattern 32 exposing regions where the device isolation regions 33 are to be formed.

The substrate 31 is dry etched to form the device isolation regions 33 having a trench structure using the photoresist pattern 32 as an etch mask. The device isolation regions 33 are formed to a depth ranging from approximately 1,000 Å to approximately 1,500 Å. The device isolation regions 33 are parts of intended trenches for device isolation. That is, the device isolation regions 33 are formed with a smaller depth than the intended trenches.

The photoresist pattern 32 can provide sufficient etching without using a pad nitride layer and a pad oxide layer, which have been used in typical semiconductor devices, because the device isolation regions 33 are formed in the small depth ranging from approximately 1,000 Å to approximately 1,500 Å. Typically, the pad oxide layer has been formed to lessen a stress between the pad nitride layer and a substrate, and the pad nitride layer has been formed as a hard mask to increase an etch margin of a photoresist layer. That is, the depth of the device isolation regions 33 ranging from approximately 1,000 Å to approximately 1,500 Å provides a sufficient level of selectivity to the photoresist pattern 32.

As shown in FIG. 3B, the photoresist pattern 32 is removed using oxygen plasma. A barrier layer 34 is formed over the substrate 31 and the device isolation regions 33. The barrier layer 34 is formed to be used as an etch barrier and a hard mask during a subsequent etching process for forming bottom portions of the device isolation regions 33. The barrier layer 34 includes an oxide-based layer, especially an undoped silicate glass (USG) layer, which has a very low step coverage characteristic. The USG layer obtains a low step coverage characteristic when formed by employing a plasma enhanced chemical vapor deposition (PECVD) method.

For example, if an USG layer is formed over an upper surface of the substrate 31 in a thickness of approximately 300 Å, where the device isolation regions 33 are not formed, the USG layer is formed on a bottom surface of the device isolation regions 33 in a thickness ranging from approximately 20 Å to approximately 50 Å. Therefore, if portions of the barrier layer 34 are formed over the upper surface of the substrate 31 in a thickness ranging from approximately 500 Å to approximately 700 Å, where the device isolation regions 33 are not formed, then the portions of the barrier layer 34 formed over the upper surface of the substrate 31 can function as a hard mask instead of the pad nitride layer, which has been used as a typical hard mask. Meanwhile, portions of the barrier layer 34 formed over the bottom surface of the device isolation regions 33 are formed in a small thickness. Thus, the portions of the barrier layer 34 formed over the bottom surface of the device isolation regions 33 can be easily etched away during the subsequent etching process for forming the bottom portions of the device isolation regions 33.

As shown in FIG. 3C, the barrier layer 34 is selectively etched to expose the bottom surface of the device isolation regions 33. The portions of the barrier layer 34 formed over the bottom surface of the device isolation regions 33 are easily etched away because of the small thickness, and thus, patterned barrier layer 34A is formed.

Portions of the substrate 31 below the exposed bottom surface of the device isolation regions 33 are etched to form bottom portions 35 having a trench structure using the patterned barrier layer 34A as an etch barrier. The bottom portions 35 are parts of the device isolation regions 33, and are referred to as the bottom portions 35 for convenience.

Reference numeral 31A denotes a patterned substrate after the formation of the bottom portions 35. Consequently, the patterned barrier layer 34A is not formed on sidewalls of the bottom portions 35, but is formed on sidewalls of the device isolation regions 33.

As shown in FIG. 3D, an isotropic etching process is performed onto the bottom portions 35 to transform the bottom portions 35 into rounded bottom portions 35A having a larger width than the device isolation regions 33. The isotropic etching process is performed at a dry etch apparatus attached with a microwave generator. A chlorine (Cl₂) gas flows at a rate ranging from approximately 100 sccm to approximately 200 sccm, and a mixture gas including hydrogen bromide (HBr) and methane (CH₄) flows at a rate ranging from approximately 50 sccm to approximately 100 sccm. Since the microwave generator holds ions having straightness among ions of a plasma, the ions having straightness cannot reach the patterned substrate 31A at the bottom. Thus, only radicals which perform a chemical etching are allowed to etch the bottom portion of the patterned substrate 31A (i.e., the bottom portions 35), widening the surface area.

Referring to FIG. 3E, a wet cleaning process is employed to remove the patterned barrier layer 34A. The wet cleaning process uses a diluted hydrogen fluoride (HF) solution. A ratio of water to HF in the diluted HF solution is in a range of approximately 15-25:1. The wet cleaning process is performed for approximately 30 seconds to approximately 45 seconds.

Although not illustrated, an insulation material is formed over the resultant substrate structure to fill the intended trenches including the device isolation regions 33 and the rounded bottom portions 35A. Then, a planarizing process is performed to form device isolation structures 36.

The device isolation structures 36 filled in the intended trenches are formed in a flask shape because the bottom portions 35A has a round shape. Thus, a distance between the device isolation structures 36 increases, and horns which may be formed between recess channels and the device isolation structures 36 during a subsequent process for forming the recess channels can be reduced.

As shown in FIG. 3F, predetermined portions of the patterned substrate 31A are etched to form recess channels 37. In more detail, a hard mask and a photoresist layer are formed over the patterned substrate 31A. A patterning process is performed onto the hard mask and the photoresist layer. Then, the predetermined portions of the patterned substrate 31A are etched using the patterned photoresist layer and the hard mask.

In accordance with the specific embodiment of the present invention, the trenches are formed without using the pad oxide layer and the pad nitride layer. The trenches are formed in a flask shape to increase the distance between the device isolation structures, and the horns which may form between the device isolation structures and the recess channels are removed to improve the device characteristics.

The present application contains subject matter related to the Korean patent application No. KR 2005-122472, filed in the Korean Patent Office on Dec. 13, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, the method comprising:
etching a predetermined portion of a substrate to form a device isolation region;
forming a barrier layer over the substrate and the device isolation region;
selectively etching the barrier layer to expose a bottom surface of the device isolation region;
etching the exposed bottom surface of the device isolation region using the barrier layer as an etch barrier;
performing an isotropic etching process onto a bottom portion of the device isolation region; and
forming a device isolation structure filled into the device isolation region.

2. The method of claim 1, wherein the forming of the device isolation region comprises:
forming a photoresist pattern over the substrate, the photoresist pattern exposing a predetermined portion of the substrate for the device isolation region;
etching the predetermined portion of the substrate to form a trench using the photoresist pattern as an etch barrier; and
removing the photoresist pattern.

3. The method of claim 2, wherein the etching of the predetermined portion of the substrate to form the trench comprises performing a dry etching process.

4. The method of claim 3, wherein the trench is formed to a depth ranging from approximately 1,000 Å to approximately 1,500 Å.

5. The method of claim 1, wherein the forming of the barrier layer comprises forming a portion of the barrier layer over an upper surface of the substrate with a larger thickness than portions of the barrier layer formed over bottom and sidewall surfaces of the device isolation region.

6. The method of claim 5, wherein the forming of the barrier layer comprises using a plasma enhanced chemical vapor deposition (PECVD) method.

7. The method of claim 6, wherein the forming of the barrier layer comprises including an oxide-based layer.

8. The method of claim 7, wherein the oxide-based layer includes an undoped silicate glass (USG) layer.

9. The method of claim 8, wherein the USG layer is formed to a thickness ranging from approximately 500 Å to approximately 700 Å over the upper surface of the substrate.

10. The method of claim 1, wherein the etching of the predetermined portion of the substrate to form the device isolation region comprises performing a dry etching process.

11. The method of claim 1, wherein the performing of the isotropic etching process onto the bottom portion of the device isolation region comprises using a dry etch apparatus attached with a microwave generator.

12. The method of claim 11, wherein the performing of the isotropic etching process onto the bottom portion of the device isolation region comprises using chlorine (Cl₂) gas, added with a mixture gas including hydrogen bromide (HBr) gas, and methane (CH₄) gas.

13. The method of claim 12, wherein the Cl₂ gas flows at a rate ranging from approximately 100 sccm to approximately 200 sccm.

14. The method of claim 12, wherein the mixture gas flows at a rate ranging from approximately 50 sccm to approximately 100 sccm.

15. The method of claim 1, further comprising removing the barrier layer after the performing of the isotropic etching process onto the bottom portion of the device isolation region.

16. The method of claim 15, wherein the removing of the barrier layer comprises using a wet cleaning process.

17. The method of claim 16, wherein the wet cleaning process comprises using a diluted solution of hydrogen fluoride (HF) having a ratio of water to HF in a range of approximately 15-25:1.

18. The method of claim 17, wherein the wet cleaning process is performed for approximately 30 seconds to approximately 45 seconds.
